(19) United States
(12) Patent Application Publication
(10) Pub. No.: US 2010/0032780 A1
(43) Pub. Date: Feb. 11, 2010

(54) MRAM WITH EDDY CURRENT BARRIER

(75) Inventor: Kor Seng ANG, Singapore (SG)

Correspondence Address: SUGHRUE MION, PLLC, 2100 PENNSYLVANIA AVENUE, N.W., SUITE 800, WASHINGTON, DC, 20037, US

(73) Assignee: Showa Denko HD Singapore Pte Ltd, Singapore (SG)

(21) Appl. No.: 12/505,818

(22) Filed: Jul. 20, 2009

(30) Foreign Application Priority Data
Aug. 5, 2008 (SG) 200805894-3

(51) Int. Cl. H01L 29/82; B05D 5/00; C23C 14/34

(52) U.S. Cl. 257/421; 427/131; 204/192.1; 257/E29.323

(57) ABSTRACT

Disclosed is a magnetoresistive random access memory (“MRAM”) device comprising a plurality of layers on a substrate. The plurality of layers comprises pinning layers, flipping layers, and at least one insulating layer between the pinning layers and the flipping layers. An eddy current side wall encapsulates at least the pinning layers of the plurality of layers. The eddy current side wall comprises a grain insulating layer for electrical insulation, and a magnetic barrier layer for magnetic isolation.

### TECHNICAL FIELD

This invention relates to magnetoresistive random access memory (“MRAM”) with an eddy current barrier and refers particularly, though not exclusively, to MRAM with an eddy current barrier to reduce eddy current interference.

### BACKGROUND

A known MRAM structure is schematically shown in FIG. 1. On a substrate 101 are: a reference layer 103, an interface layer 105, an insulating layer 107, a second interface layer 109, and a free layer 111. A cap layer 113 is the topmost layer and is opposite the substrate 101. The electric current is shown by arrow 115 and magnetic pinning by arrow 117. Magnetic flipping is bidirectional as shown by arrow 119.

With MRAM, as each device is scaled down, the induced magnetic field may overlap with adjacent cells, leading to potentially incorrect writes in the adjacent cell. This problem is sometimes called the half-select or write disturb problem. As such it has been long believed that MRAM is limited to a relatively large cell size. Also, during fast write cycles, eddy current tunneling may result in leakage to an adjacent cell. The problem is mainly in the second interface layer 109, and free layer 111, where external interference, particularly from the pinning layers 103, 105 of an adjacent cell, may cause an incorrect write in the flipping layers 109, 111.

Furthermore, for some time MRAM has been suggested as having lower switching energy with faster switching speed. However, by placing the individual cells close to each other, magnetic stray field interference can happen due to pin layer magnetic orientation.

### SUMMARY

According to an exemplary aspect there is provided a magnetoresistive random access memory (“MRAM”) device comprising a plurality of layers on a substrate. The plurality of layers comprises pinning layers, flipping layers, and at least one insulating layer between the pinning layers and the flipping layers. An eddy current side wall encapsulates at least the pinning layers of the plurality of layers. The eddy current side wall comprises a grain insulating layer for electrical insulation, and a magnetic barrier layer for magnetic isolation.

The MRAM device may further comprise a cap layer on the plurality of layers remote from the substrate. The eddy current side wall may extend between the substrate and the cap layer for reducing potential interference both magnetically and electrically. The grain insulating layer may be over the flipping layers, and the magnetic barrier layer may be over the grain insulating layer.

According to another exemplary aspect there is provided a magnetoresistive random access memory (“MRAM”) device comprising a plurality of layers on a substrate. The plurality of layers comprises pinning layers, flipping layers, and at least one insulating layer between the pinning layers and the flipping layers.

A cap layer is over the plurality of layers remote from the substrate. An eddy current side wall encapsulates and insulating the plurality of layers. The eddy current side wall extends from and between the cap layer and the substrate.

For both aspects the eddy current side wall may extend between an upper surface of the substrate to at least one of a side wall and a lower surface of the cap layer.

According to a further exemplary aspect, there is provided a method of insulating a magnetoresistive random access memory (“MRAM”) device. The MRAM device comprises a plurality of layers on a substrate. The plurality of layers comprises pinning layers, flipping layers, and at least one insulating layer between the pinning layers and the flipping layers. The method comprises forming an eddy current side wall encapsulating at least the pinning layers of the plurality of layers. The eddy current barrier is formed by first forming one of a grain insulating layer for electrical insulation and a magnetic barrier layer for magnetic isolation, then forming the other of the grain insulating layer for electrical insulation and the magnetic barrier layer for magnetic isolation.

For the further aspect, the grain insulating layer for electrical insulation may be formed over side walls of at least the plurality of flipping layers. The magnetic barrier layer may be formed over the grain insulating layer. Before forming the eddy current side wall, a photoresist layer may be formed over those surfaces where the eddy current side wall is not required. The eddy current side wall may be formed by one of: plating, and sputtering. The method may further comprise forming a cap layer on the plurality of layers remote from the substrate. The eddy current side wall may be formed between the substrate and the cap layer for reducing potential interference both magnetically and electrically. The eddy current side wall may be formed between an upper surface of the substrate to at least one of a side wall and a lower surface of the cap layer.

For all aspects, the magnetic barrier layer may comprise a material having relatively high paramagnetic properties. The material may be selected from: copper, and a compound of copper having a high copper content. The grain insulating layer may comprise: an O₃ compound, or an O₃ compound of a metal. The grain insulating layer may be: Al₂O₃, Fe₂O₃ or B₂O₃.

### BRIEF DESCRIPTION OF THE DRAWINGS

In order that the invention may be fully understood and readily put into practical effect there shall now be described by way of non-limitative example only exemplary embodiments, the description being with reference to the accompanying illustrative drawings.

In the drawings:

FIG. 1 is a schematic illustration of a known, typical MRAM structure;

FIG. 2 is a schematic illustration of an exemplary embodiment of an MRAM structure; and

FIG. 3 is a schematic illustration of another exemplary embodiment of an MRAM structure.

### DETAILED DESCRIPTION OF THE EXEMPLARY EMBODIMENTS

In the drawings like components have like reference numerals with a prefix number indicating the relevant drawing figure.

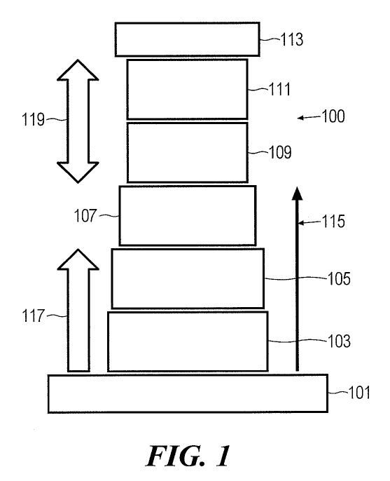

As mentioned above, a known MRAM structure 100 is schematically shown in FIG. 1. On a substrate 101 are: a reference layer 103, an interface layer 105, an insulating layer 107, a second interface layer 109, and a free layer 111. A cap layer 113 is the topmost layer and is opposite the substrate 101107 (as an electrical connection layer). A grain-to-grain insulator (not shown) is provided. The electric current is shown by arrow 115 and magnetic pinning by arrow 117. Magnetic flipping is bidirectional as shown by arrow 119. This structure suffers from the half-select or write disturb problem; eddy current tunneling during fast write cycles; eddy current leakage to an adjacent cell; magnetic stray field interference; and imperfect anisotropy uniformity during thermal conditions.

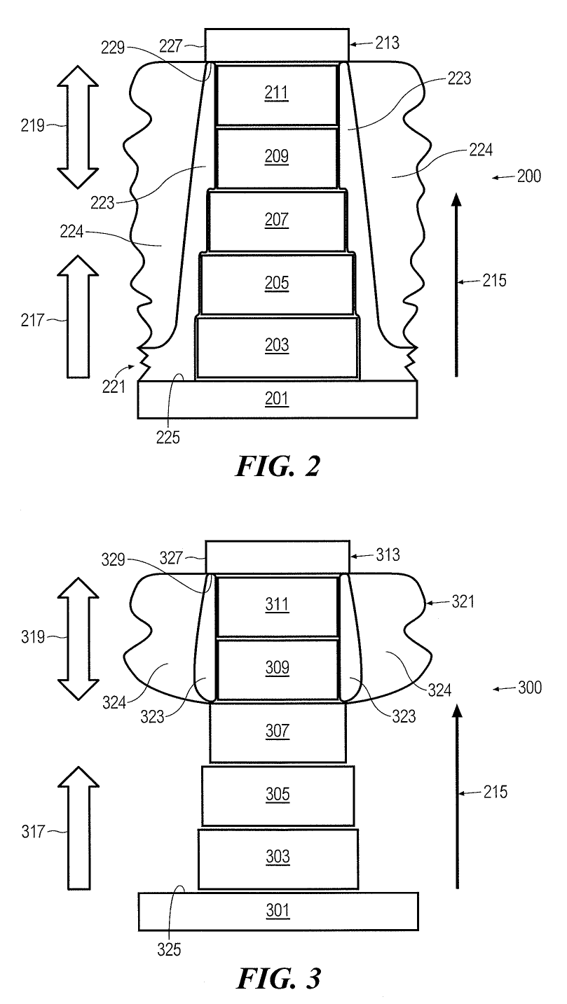

In FIG. 2 there is shown an exemplary embodiment of an MRAM structure 200. On a substrate 201 are: a reference layer 203, an interface layer 205, an insulating layer 207, a second interface layer 209, and a free layer 211. A cap layer 213 is the topmost layer and is opposite the substrate 201. The electric current is shown by arrow 215 and magnetic pinning by arrow 217. Magnetic flipping is bidirectional as shown by arrow 219. All of this is similar to the known structure of FIG. 1. In addition, for the exemplary embodiment there is an eddy current side wall generally designated as 221 over the MRAM structure 200.

The eddy current side wall 221 is not conducive to conducting eddy currents and is also generally electrically insulating. It has two component layers: a grain isolation layer 223 for electrical insulation, and a magnetic barrier layer 224 for magnetic isolation. As shown, the grain isolation layer 223 is immediately adjacent the MRAM structure 200 and the magnetic barrier layer 224 is applied over the grain isolation layer 223. However, the magnetic barrier layer 224 may be immediately adjacent the MRAM structure 200, and the grain isolation layer 223 may be applied over the magnetic barrier layer 224.

The grain isolation layer 223 is of a material that provides electrical current protection preferably by electrically shorting an external interference signal. It may be of any suitable material such as, for example, an O₃ compound, particularly an O₃ compound of a metal. A metal is preferred for rigidity. For example, the grain isolation layer 223 may be one or more of: Al₂O₃, Fe₂O₃ and B₂O₃. The grain isolation layer 223 covers at least the flipping layers 209, 211 to shield them from external signals that may cause incorrect writes; and also may stop interference signals emanating from the flipping layers 209, 211. Preferably, the grain isolation layer 223 fully encapsulates the MRAM structure 200 from an upper surface 225 of the substrate 201 to a side wall 227 or lower surface 229 of the cap layer 213.

The grain isolation layer 223 may be applied using known techniques such as, for example, plating or sputtering of AlO or SiO, after applying a photoresist layer to those surfaces not requiring the grain layer 223 (e.g. the top of free layer 211 or cap layer 213).

The magnetic barrier layer 224 is of a material having relatively high paramagnetic properties such as for example, Cu, or Al, and covers at least the flipping layers 209, 211 to shield them from external magnetic signals that may cause incorrect writes; and also may stop magnetic interference signals emanating from the flipping layers 209, 211. Preferably, the magnetic barrier layer 224 fully encapsulates the MRAM structure 200 from an upper surface 225 of the substrate 201 to a side wall 227 or lower surface 229 of the cap layer 213. The magnetic barrier layer 224 may be of any suitable material having relatively high paramagnetic properties such as, for example, copper or a compound of copper having a high copper content.

The magnetic barrier layer 224 may be applied using known techniques such as, for example, plating or sputtering, after applying a photoresist layer to those surfaces not requiring the magnetic barrier layer 224 (e.g. the top of free layer 211 or cap layer 213).

Therefore, the MRAM structure 200 is shielded from external interference by the eddy current side wall 221, the cap layer 213 and the substrate 201. The external interference may be from one or more adjacent cells or from another source such as, for example, a power supply.

FIG. 3 shows a variation. Here, only the flipping layers 309, 311 having applied thereto the eddy current side wall 321. There is no eddy current side wall 321 over the pinning layers 313, 305 or the insulating layer 307. The structure of the eddy current side wall 321 is the same and it is formed in the same manner as described above. The photoresist would therefore be applied to the side walls of the pinning layers 303, 305 as wall as the insulating layer 307.

In both exemplary embodiments, the MRAM structure 200, 300 should not suffer from one or more of:
the half-select or write disturb problem;
eddy current tunneling during fast write cycles;
eddy current leakage to an adjacent cell;
magnetic stray field interference; and
imperfect anisotropy uniformity during thermal conditions.

Furthermore, the addition of the eddy current side wall 221, 321 may:
reduce potential interference between cells both magnetically and electrically;
enable higher density MRAM as it will permit closer cell spacing; and
improve per wafer density.

Whilst the foregoing description has described exemplary embodiments, it will be understood by those skilled in the technology concerned that many variations in details of design, construction and/or operation may be made without departing from the present invention.

1. A magnetoresistive random access memory (“MRAM”) device comprising:
a plurality of layers on a substrate, the plurality of layers comprising pinning layers, flipping layers, and at least one insulating layer between the pinning layers and the flipping layers; and
an eddy current side wall encapsulating at least the pinning layers of the plurality of layers, the eddy current side wall comprising a grain insulating layer for electrical insulation, and a magnetic barrier layer for magnetic isolation.

2. A MRAM device as claimed in claim 1 further comprising a cap layer on the plurality of layers remote from the substrate.

3. A MRAM device as claimed in claim 2, wherein the eddy current side wall extends between the substrate and the cap layer for reducing potential interference both magnetically and electrically.

4. A magnetoresistive random access memory (“MRAM”) device comprising:
a plurality of layers on a substrate, the plurality of layers comprising pinning layers, flipping layers, and at least one insulating layer between the pinning layers and the flipping layers;
a cap layer over the plurality of layers remote from the substrate; and
an eddy current side wall encapsulating and insulating the plurality of layers, the eddy current side wall extending from and between the cap layer and the substrate.

5. A MRAM device as claimed in claim 4, wherein the eddy current side wall extends between an upper surface of the substrate to at least one of a side wall and a lower surface of the cap layer.

6. A MRAM device as claimed in claim 1, wherein the magnetic barrier layer comprises a material having relatively high paramagnetic properties.

7. A MRAM device as claimed in claim 6, wherein the material is selected from the group consisting of: copper, and a compound of copper having a high copper content.

8. A MRAM device as claimed in claim 1, wherein the grain insulating layer comprises at least one selected from the group consisting of: an O₃ compound, and an O₃ compound of a metal.

9. A MRAM device as claimed in claim 8, wherein the grain insulating layer is selected from the group consisting of: Al₂O₃, Fe₂O₃ and B₂O₃.

10. A MRAM device as claimed in claim 6, wherein the grain insulating layer is over the flipping layers, and the magnetic barrier layer is over the grain insulating layer.

11. A method of insulating a magnetoresistive random access memory (“MRAM”) device, the MRAM device comprising a plurality of layers on a substrate, the plurality of layers comprising pinning layers, flipping layers, and at least one insulating layer between the pinning layers and the flipping layers; the method comprising:
forming an eddy current side wall encapsulating at least the pinning layers of the plurality of layers, the eddy current barrier being formed by first forming one of a grain insulating layer for electrical insulation and a magnetic barrier layer for magnetic isolation, then forming the other of the grain insulating layer for electrical insulation and the magnetic barrier layer for magnetic isolation.

12. A method as claimed in claim 11, wherein the grain insulating layer for electrical insulation is formed over side walls of at least the plurality of flipping layers and the magnetic barrier layer is formed over the grain insulating layer.

13. A method as claimed in claimed in claim 11, wherein before forming the eddy current side wall, a photoresist layer is formed over those surfaces where the eddy current side wall is not required; the eddy current side wall being formed by one of: plating, and sputtering.

14. A method as claimed in claim 11 further comprising forming a cap layer on the plurality of layers remote from the substrate.

15. A method as claimed in claim 14, wherein the eddy current side wall is formed between the substrate and the cap layer for reducing potential interference both magnetically and electrically.

16. A method as claimed in claim 15, wherein the eddy current side wall is formed between an upper surface of the substrate to at least one of a side wall and a lower surface of the cap layer.

17. A method as claimed in claim 11, wherein the magnetic barrier layer comprises a material having relatively high paramagnetic properties.

18. A method as claimed in claim 17, wherein the material is selected from the group consisting of: copper, and a compound of copper having a high copper content.

19. A method as claimed in claim 11, wherein the grain insulating layer comprises at least one selected from the group consisting of: an O₃ compound, and an O₃ compound of a metal.

20. A method as claimed in claim 19, wherein the grain insulation layer is selected from the group consisting of: Al₂O₃, Fe₂O₃ and B₂O₃.
